(19) United States
(12) Patent Application Publication
(10) Pub. No.: US 2026/0359538 A1
(43) Pub. Date: Nov. 12, 2026

(54) METHOD AND COMPUTING SYSTEM FOR GENERATING DEVICE TREE FILE

(71) Applicant: Jabil Circuit (Singapore) Pte. Ltd., Singapore (SG)

(72) Inventors: Tsu-Chin Lin, Taichung City (TW); Yi-Ching Chen, Taichung City (TW); Shuo-Hung Hsu, New Taipei City (TW)

(73) Assignee: Jabil Circuit (Singapore) Pte. Ltd., Singapore (SG)

(21) Appl. No.: 19/401,849

(22) Filed: Nov. 26, 2025

(30) Foreign Application Priority Data
May 8, 2025 (CN) 202510593112.0

(51) Int. Cl. G06F 30/343

(52) U.S. Cl. CPC G06F 30/343

(57) ABSTRACT

A method for generating a device tree file is adapted to be implemented by a controller, and includes steps of: obtaining field-replaceable unit (FRU) data from a programmable logic device connected to the controller; obtaining topological data related to a device tree for describing hardware devices based on the FRU data; obtaining a device tree source (DTS) file based on the topological data and templates that are stored in the controller, that are related to types of nodes, and that are expressed in a DTS format; and compiling the DTS file into a device tree binary (DTB) file.

### CROSS-REFERENCE TO RELATED APPLICATION

This application claims priority to Chinese Invention Patent Application No. 202510593112.0, filed on May 8, 2025, the entire disclosure of which is incorporated by reference herein.

### FIELD

The disclosure relates to a method and a computing system for generating a device tree file.

### BACKGROUND

A device tree is a kind of data structure, and is used for describing hardware devices. A device tree source (DTS) format is a textual representation of a device tree in a form that can be processed by a device tree compiler (DTC) into a device tree blob (DTB). DTB is a binary file and can be utilized by a kernel of an operating system (e.g., an embedded Linux operating system) in a booting process.

Patent number CN115756624 discloses a method for loading a DTB file of a device tree. Therein, the method includes steps of: building a public work; obtaining a plurality of DTS files and adding the DTS files into a kernel source code packet of the newly-built public work to generate a plurality of DTB files; obtaining a project board identifier that corresponds to a new project and looking up a DTB file name of the device tree in a preset structure table; and loading the corresponding one of the DTB files in the kernel source code packet according to the DTB file name thus looked up. However, in such an approach, the DTS files have to be manually generated by technicians in advance and require a relatively large storage for storing the DTS files.

### SUMMARY

Therefore, an object of the disclosure is to provide a method and a computing system for generating a device tree file that can alleviate at least one of the drawbacks of the prior art.

According to one aspect of the disclosure, the computing system includes a plurality of hardware devices, a programmable logic device and a controller.

The programmable logic device is electrically connected to the plurality of hardware devices, and is configured to provide multiple entries of field-replaceable unit (FRU) data related respectively to the plurality of hardware devices.

The controller is electrically connected to the programmable logic device. The controller stores multiple templates that are related respectively to multiple types of nodes and that are expressed in a device tree source (DTS) format. The controller is configured to obtain the multiple entries of FRU data from the programmable logic device. The controller is configured to obtain topological data related to a device tree for describing the plurality of hardware devices of the computing system based on the multiple entries of FRU data. The topological data contains, for each hardware device of the plurality of hardware devices, device information related to the hardware device and connection information related to connection between the hardware device and other ones of the plurality of hardware devices. The controller is configured to obtain a DTS file based on the templates and the topological data. The controller is configured to compile the DTS file into a device tree binary (DTB) file.

According to another aspect of the disclosure, the method is adapted to be implemented by the controller of the computing system that is previously described. The method includes steps of:
obtaining multiple entries of FRU data from the programmable logic device;
obtaining topological data related to a device tree for describing the plurality of hardware devices of the computing system based on the multiple entries of FRU data;
obtaining a DTS file based on the templates and the topological data; and
compiling the DTS file into a DTB file.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a computing system according to an embodiment of the disclosure.

FIG. 2 is a flow chart illustrating a method for generating a device tree file according to an embodiment of the disclosure.

FIG. 3 is a schematic diagram illustrating an example of topological data according to an embodiment of the disclosure.

FIG. 4 is a flow chart illustrating sub-steps of obtaining a DTS file in the method according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

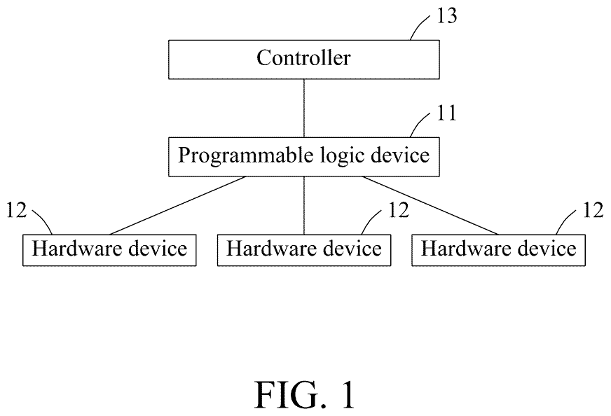

Referring to FIG. 1, an embodiment of a computing system for generating a device tree file according to the disclosure is illustrated. The computing system may be implemented to be a server system, but is not limited thereto. The computing system includes a plurality of hardware devices 12, a programmable logic device 11 and a controller 13.

The programmable logic device 11 is electrically connected to the hardware devices 12. The programmable logic device 11 is configured to provide multiple entries of field-replaceable unit (FRU) data that are related respectively to the hardware devices 12. It is worthy of note that for each of the hardware devices 12, the entry of FRU data related to the hardware device 12 contains device information related to the hardware device 12 and connection information related to connection between the hardware device 12 and other ones of the hardware devices 12. The programmable logic device 11 may be implemented to be a field-programmable gate array (FPGA), but is not limited thereto.

The controller 13 is electrically connected to the programmable logic device 11. The controller 13 may be implemented to be a baseboard management controller (BMC), but is not limited thereto. Since the BMC has been well known to one skilled in the relevant art, detailed explanation of the same is omitted herein for the sake of brevity. The controller 13 includes a main processing module (not shown) and an auxiliary processing module (not shown) that are electrically connected to each other. However, in some embodiments, the main processing module and the auxiliary processing module are separated and not electrically connected to each other. The auxiliary processing module of the controller 13 stores multiple templates that are related respectively to multiple types of nodes and that are expressed in a device tree source (DTS) format. Specifically, the templates include a root-device template that is related to a root node (which is usually implemented by a root device such as a bus, and is also known as a data highway or a databus), a multiplexer template that is related to a multiplexer (which has multiple channels), a channel template that is related to a channel of a multiplexer, and a non-multiplexer template that is related to a non-multiplexer device. It is worthy of note that in this embodiment, the nodes are connected in an Inter-Integrated Circuit (I²C) bus topology with multiplexers as shown in the following paragraphs, but the topology of the nodes is not limited to the disclosure herein and may vary to support other types of buses in other embodiments. For example, in some embodiments, the nodes are connected in an Improved Inter Integrated Circuit (I³C) bus topology.

An example of the root-device template is shown below.

```
&$Buses.I2C.$Identifier {
  status = “okay”;
  # Find I2C.$Identifier == “I2C-0”
  # Load ‘Without Mux I2C Template’ for each ‘Devices’ at the same
  layer
  # Load ‘With Mux I2C Template’
};
```

An example of the non-multiplexer template is shown below.

```
$Identifier@$Address {
  compatible = “$Compatible”;
  reg = <$Address>;
};
```

An example of the multiplexer template is shown below.

```
/* I2C MUX Definition */
i2c_switch@$Muxes.Address {
  compatible = “$Compatible”;
  reg = <$Muxes.Address>;
  #address-cells = <1>;
    #size-cells = <0>;
i2c-mux-idle-disconnect;
  # Load ‘Without Mux I2C Template’ for each ‘Devices’ at the same
  layer
};
```

An example of the channel template is shown below.

```
i2c@$Muxes.Channels.Channel {
  reg = <$Muxes.Channels.Channel>;
  #address-cells = <1>;
  #size-cells = <0>;
  # Load ‘Without Mux I2C Template’ for each ‘Devices’ at the same
  layer
  };
```

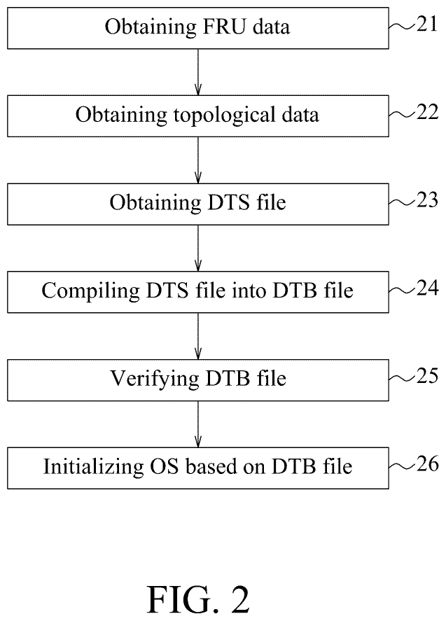

Referring to FIG. 2, an embodiment of a method for generating a device tree file according to the disclosure is illustrated. The method is adapted to be implemented by the controller 13 of the computing system that is previously described. The method includes steps 21 to 26 delineated below.

In step 21, the auxiliary processing module of the controller 13 obtains the multiple entries of FRU data from the programmable logic device 11.

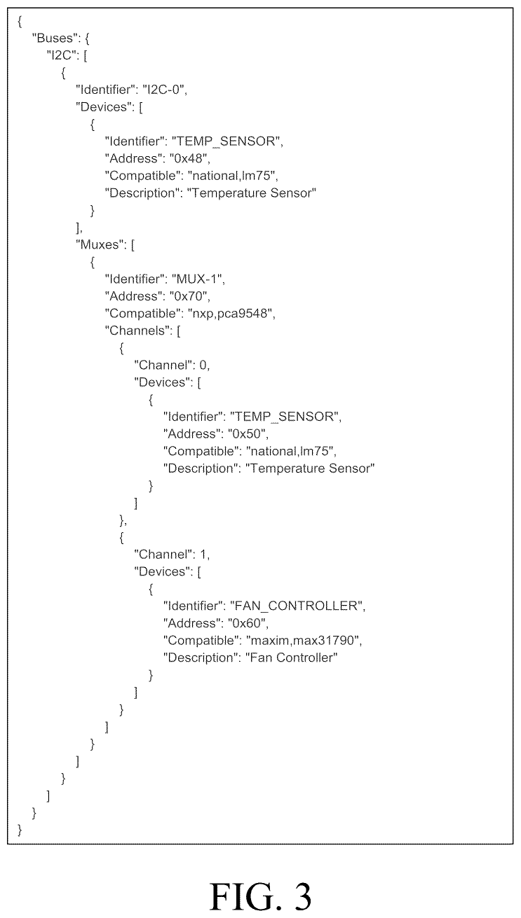

In step 22, the auxiliary processing module of the controller 13 obtains topological data related to a device tree for describing the plurality of hardware devices 12 of the computing system based on the multiple entries of FRU data. Similar to the multiple entries of FRU data, the topological data contains, for each hardware device 12 of the plurality of hardware devices 12, device information related to the hardware device 12 and connection information related to connection between the hardware device 12 and other ones of the plurality of hardware devices 12. Specifically, in this embodiment, the topological data is in a JSON (JavaScript Object Notation) format as shown in FIG. 3. Since converting the entries of FRU data into the topological data has been well known to one skilled in the relevant art, detailed explanation of the same is omitted herein for the sake of brevity.

In step 23, the auxiliary processing module of the controller 13 obtains a DTS file based on the templates and the topological data.

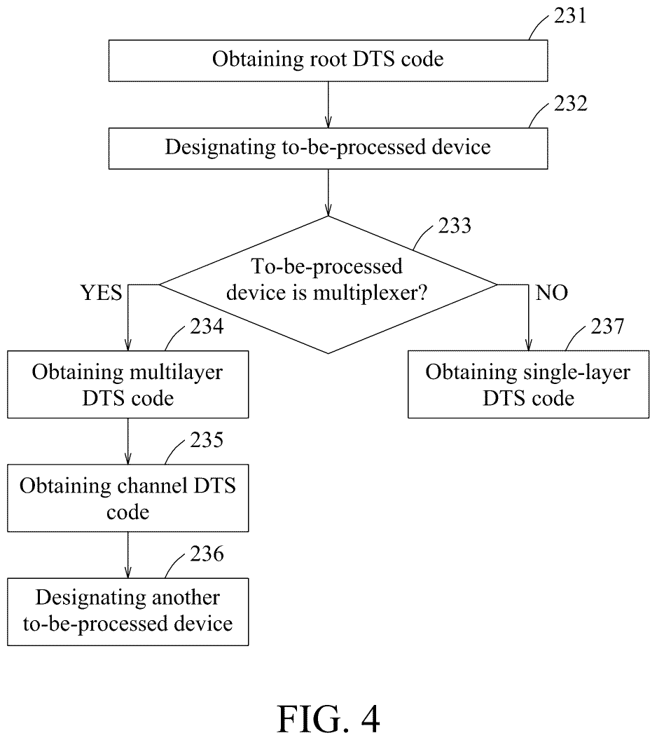

Specifically, referring to FIG. 4, step 23 includes sub-steps 231 to 237 delineated below.

In sub-step 231, for a root device (e.g., a bus) among the plurality of hardware devices 12 that is a root node of the device tree, the auxiliary processing module of the controller 13 converts the device information related to the root device in the topological data (see FIG. 3) into a root DTS code based on the root-device template. An example of the root DTS code is shown below.

&i2c_0 {
status = “okay”;
};

In sub-step 232, for each child device among the plurality of hardware devices 12 that is a child node of the root node, the auxiliary processing module of the controller 13 designates the child device as a to-be-processed device. For each to-be-processed device, the auxiliary processing module of the controller 13 executes a traversing procedure. The traversing procedure includes sub-steps 233 to 237 described as follows.

In sub-step 233, the auxiliary processing module of the controller 13 determines whether the to-be-processed device is a multiplexer. In response to determining that the to-be-processed device is a multiplexer, a procedure flow of the method proceeds to sub-step 234. Otherwise, in response to determining that the to-be-processed device is not a multiplexer, the procedure flow proceeds to sub-step 237.

In sub-step 234, the auxiliary processing module of the controller 13 converts the device information related to the to-be-processed device included in the topological data into a multilayer DTS code based on the multiplexer template. Then, the auxiliary processing module of the controller 13 places the multilayer DTS code thus converted at a nested layer of a DTS code that is related to a parent node of the to-be-processed device in the device tree. For example, in a scenario where the parent node of the to-be-processed device in the device tree is the root device, the DTS code related to the parent node is the root DTS code, and the multilayer DTS code would be placed at a nested layer of the root DTS code. An example of the multilayer DTS code placed at the nested layer of the root DTS code is shown below.

```
&i2c_0 {
  status = “okay”;
    i2c_switch@70 {
    compatible = “nxp,pca9548”;
    reg = <0x70>;
    #address-cells = <1>;
        #size-cells = <0>;
    i2c-mux-idle-disconnect;
      };
  };
```

In sub-step 235, for each of the channels of the multiplexer, the auxiliary processing module of the controller 13 converts a part of the device information related to the channel into a channel DTS code based on the channel template, and places the channel DTS code thus converted at a nested layer of the multilayer DTS code. An example of the channel DTS code(s) placed at the nested layer of the multilayer DTS code is shown below.

```
i2c_switch@70 {
compatible = “nxp,pca9548”;
reg = <0x70>;
#address-cells = <1>;
    #size-cells = <0>;
i2c-mux-idle-disconnect;
  i2c@0 {
    reg = <0>;
          #address-cells = <1>;
          #size-cells = <0>;
  };
        i2c@1 {
    reg = <1>;
          #address-cells = <1>;
          #size-cells = <0>;
  };
      };
```

It should be noted that each channel of the multiplexer is a child node of the multiplexer in the device tree. In other words, the multiplexer is a parent node of each chancel of the multiplexer in the device tree. Hence, referring back to sub-step 234, in a scenario where the parent node of the to-be-processed device in the device tree is a channel of a multiplexer, the DTS code related to the parent node is the channel DTS code, and the multilayer DTS code obtained in sub-step 234 would be placed at a nested layer of the channel DTS code.

In sub-step 236, for each child device among the hardware devices 12 that is a child node of the channel in the device tree and that is connected to the to-be-processed device (i.e., the multiplexer) directly via the channel, the auxiliary processing module of the controller 13 designates the child device as another to-be-processed device, and repeats execution of the traversing procedure (i.e., sub-steps 233 to 237 are executed again for said another to-be-processed device). It should be noted that in a scenario where no hardware device is connected to the multiplexer directly via a channel of the multiplexer, the traversing procedure would not be executed for that channel.

In sub-step 237, the auxiliary processing module of the controller 13 converts the device information related to the to-be-processed device in the topological data into a single-layer DTS code based on the non-multiplexer template. Then, the auxiliary processing module of the controller 13 places the single-layer DTS code thus converted at the nested layer of the DTS code that is related to the parent node of the to-be-processed device in the device tree.

For example, in a scenario where the parent node of the to-be-processed device in the device tree is the root device, the DTS code related to the parent node is the root DTS code, and the single-layer DTS code would be placed at the nested layer of the root DTS code. An example of the single-layer DTS code that is related to a temperature sensor and that is placed at the nested layer of the root DTS code is shown below.

```
&i2c_0 {
  status = “okay”;
TEMP_SENSOR@48 {
    compatible = “national,lm75”;
    reg = <0x48>;
      };
  # Load ‘With Mux I2C Template’
};
```

In a scenario where the parent node of the to-be-processed device in the device tree is a channel of a multiplexer, the DTS code related to the parent node is the channel DTS code, and the single-layer DTS code would be placed at the nested layer of the channel DTS code. An example of the single-layer DTS code that is related to a temperature sensor and that is placed at the nested layer of the channel DTS code is shown below.

```
i2c@0 {
    reg = <0>;
        #address-cells = <1>;
        #size-cells = <0>;
        TEMP_SENSOR@50 {
      compatible = “national,lm75”;
      reg = <0x50>;
          };
  };
```

In step 24, the auxiliary processing module of the controller 13 compiles the DTS file into a device tree binary (DTB) file. Specifically, the auxiliary processing module utilizes a device tree compiler (DTC) to compile the DTS file into the DTB file.

In step 25, after compiling the DTS file, the auxiliary processing module of the controller 13 verifies the DTB file thus obtained in step 24. In particular, in this embodiment, the auxiliary processing module utilizes the DTC to determine whether or not the DTB file is correct and complete. In response to successfully verifying the DTB file (i.e., the DTB file is determined to be correct and complete), the procedure flow proceeds to step 26. On the other hand, in response to unsuccessfully verifying the DTB file (i.e., the DTB file is determined to be either incorrect or incomplete), the procedure flow returns to step 24 for compiling the DTS file into the DTB file again, and at the same time, a text output related to failure of verifying the DTB file would be outputted for notifying relevant technicians to take appropriate actions.

In step 26, the main processing module of the controller 13 initializes an operating system (e.g., an embedded Linux operating system) of the controller 13 based on the DTB file which has been successfully verified in step 25.

For explanation, in a scenario where a multiplexer and a first temperature sensor (which is a non-multiplexer device) are directly connected to the root device, a first DTS code that has been processed in sub-steps 231 to 234 and 237 but has not yet been processed in sub-step 235 is exemplarily shown below.

```
&i2c_0 {
  status = “okay”;
TEMP_SENSOR@48 {
    compatible = “national,lm75”;
    reg = <0x48>;
      };
  i2c_switch@70 {
    compatible = “nxp,pca9548”;
    reg = <0x70>;
    #address-cells = <1>;
    #size-cells = <0>;
    i2c-mux-idle-disconnect;
    };
    };
```

After sub-step 235 is executed, the above-mentioned first DTS code changes into a second DTS code shown below.

```
&i2c_0 {
  status = “okay”;
TEMP_SENSOR@48 {
    compatible = “national,lm75”;
    reg = <0x48>;
          };
  i2c_switch@70 {
    compatible = “nxp,pca9548”;
    reg = <0x70>;
    #address-cells = <1>;
    #size-cells = <0>;
    i2c-mux-idle-disconnect;
    i2c@0 {
          reg = <0>;
          #address-cells = <1>;
          #size-cells = <0>;
    };
    i2c@1 {
        reg = <1>;
        #address-cells = <1>;
        #size-cells = <0>;
      };
  };
  };
```

Following the above-mentioned example, in a scenario where a second temperature sensor is directly connected to one channel of the multiplexer and a fan controller is directly connected to another channel of the multiplexer, the above-mentioned second DTS code further changes into a third DTS code shown below after the traversing procedure has been executed for the second temperature sensor and the fan controller.

```
&i2c_0 {
  status = “okay”;
TEMP_SENSOR@48 {
    compatible = “national,lm75”;
    reg = <0x48>;
          };
  i2c_switch@70 {
    compatible = “nxp,pca9548”;
    reg = <0x70>;
    #address-cells = <1>;
    #size-cells = <0>;
    i2c-mux-idle-disconnect;
    i2c@0 {
          reg = <0>;
          #address-cells = <1>;
          #size-cells = <0>;
          TEMP_SENSOR@50 {
            compatible = “national,lm75”;
            reg = <0x50>;
          };
    };
    i2c@1 {
        reg = <1>;
        #address-cells = <1>;
        #size-cells = <0>;
        FAN_CONTROLLER@60 {
            compatible = “maxim,max31790”;
            reg = <0x60>;
        };
      };
  };
  };
```

To sum up, for the method and the computing system for generating a device tree file according to the disclosure, the controller 13 obtains the entries of FRU data from the programmable logic device 11, obtains topological data based on the entries of FRU data, obtains the DTS file based on the templates and the topological data, and compiles the DTS file into the DTB file. In this way, the DTS file can be automatically generated based on the entries of FRU data, and thus labor-saving is achieved. At the same time, human errors may be prevented and accuracy of generating a device tree file may be improved. Moreover, in response to a change of any one of the hardware devices 12 of the computing system, a new device tree file for that change may be efficiently and conveniently generated. Consequently, flexibility of generation of a device tree file may be realized.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for generating a device tree file for a plurality of hardware devices of a computing system, the computing system including a controller, and a programmable logic device that is electrically connected to the controller and the plurality of hardware devices, the controller storing multiple templates that are related respectively to multiple types of nodes and that are expressed in a device tree source (DTS) format, the method adapted to be implemented by the controller, and comprising steps of:
obtaining multiple entries of field-replaceable unit (FRU) data from the programmable logic device, the entries of FRU data being related respectively to the plurality of hardware devices;
obtaining topological data related to a device tree for describing the plurality of hardware devices of the computing system based on the multiple entries of FRU data, the topological data containing, for each hardware device of the plurality of hardware devices, device information related to the hardware device and connection information related to connection between the hardware device and other ones of the plurality of hardware devices;
obtaining a DTS file based on the templates and the topological data; and
compiling the DTS file into a device tree binary (DTB) file.

2. The method as claimed in claim 1, the templates including a root-device template that is related to a root node, a multiplexer template that is related to a multiplexer, and a channel template that is related to a channel of a multiplexer, wherein the step of obtaining the DTS file includes sub-steps of:
for a root device among the plurality of hardware devices that is a root node of the device tree, converting the device information related to the root device in the topological data into a root DTS code based on the root-device template;
for each child device among the plurality of hardware devices that is a child node of the root node, designating the child device as a to-be-processed device; and
for each to-be-processed device, executing a traversing procedure that includes
determining whether the to-be-processed device is a multiplexer, and
in response to determining that the to-be-processed device is a multiplexer having multiple channels,
converting the device information related to the to-be-processed device included in the topological data into a multilayer DTS code based on the multiplexer template,
placing the multilayer DTS code thus converted at a nested layer of a DTS code that is related to a parent node of the to-be-processed device in the device tree,
for each of the channels of the multiplexer, converting a part of the device information related to the channel into a channel DTS code based on the channel template, and placing the channel DTS code thus converted at a nested layer of the multilayer DTS code, and
for each child device among the plurality of hardware devices that is a child node of the channel in the device tree and that is connected to the to-be-processed device directly via the channel, designating the child device as another to-be-processed device, and repeating execution of the traversing procedure.

3. The method as claimed in claim 2, the templates further including a non-multiplexer template that is related to a non-multiplexer device, wherein the traversing procedure further includes:
in response to determining that the to-be-processed device is not a multiplexer,
converting the device information related to the to-be-processed device in the topological data into a single-layer DTS code based on the non-multiplexer template, and
placing the single-layer DTS code thus converted at the nested layer of the DTS code that is related to the parent node of the to-be-processed device in the device tree.

4. The method as claimed in claim 1, further comprising, after compiling the DTS file, a step of verifying the DTB file thus obtained.

5. The method as claimed in claim 4, further comprising, after verifying the DTB file, a step of:
in response to successfully verifying the DTB file, initializing an operating system of the controller based on the DTB file.

6. A computing system for generating a device tree file, comprising:
a plurality of hardware devices;
a programmable logic device electrically connected to said plurality of hardware devices, and configured to provide multiple entries of field-replaceable unit (FRU) data related respectively to said plurality of hardware devices; and
a controller electrically connected to said programmable logic device, storing multiple templates that are related respectively to multiple types of nodes and that are expressed in a device tree source (DTS) format, and configured to implement the method of claim 1.

7. The computing system as claimed in claim 6, wherein:
the templates include a root-device template that is related to a root node, a multiplexer template that is related to a multiplexer, and a channel template that is related to a channel of a multiplexer; and
said controller is configured to obtain the DTS file by:
for a root device among said plurality of hardware devices that is a root node of the device tree, converting the device information related to the root device in the topological data into a root DTS code based on the root-device template;
for each child device among said plurality of hardware devices that is a child node of the root node, designating the child device as a to-be-processed device; and
for each to-be-processed device, executing a traversing procedure that includes
determining whether the to-be-processed device is a multiplexer, and
in response to determining that the to-be-processed device is a multiplexer having multiple channels,
converting the device information related to the to-be-processed device included in the topological data into a multilayer DTS code based on the multiplexer template,
placing the multilayer DTS code thus converted at a nested layer of a DTS code that is related to a parent node of the to-be-processed device in the device tree,
for each of the channels of the multiplexer, converting a part of the device information related to the channel into a channel DTS code based on the channel template, and placing the channel DTS code thus converted at a nested layer of the multilayer DTS code, and
for each child device among said plurality of hardware devices that is a child node of the channel in the device tree and that is connected to the to-be-processed device directly via the channel, designating the child device as another to-be-processed device, and repeating execution of the traversing procedure.

8. The computing system as claimed in claim 7, wherein:
the templates further include a non-multiplexer template that is related to a non-multiplexer device; and
the traversing procedure further includes
in response to determining that the to-be-processed device is not a multiplexer,
converting the device information related to the to-be-processed device in the topological data into a single-layer DTS code based on the non-multiplexer template, and
placing the single-layer DTS code thus converted at the nested layer of the DTS code that is related to the parent node of the to-be-processed device in the device tree.

9. The computing system as claimed in claim 6, wherein said controller is further configured to, after compiling the DTS file, verify the DTB file thus obtained.

10. The computing system as claimed in claim 9, wherein said controller is further configured to, in response to successfully verifying the DTB file, initializing an operating system of the controller based on the DTB file.
